(19) United States
(12) Patent Application Publication
(10) Pub. No.: US 2010/0116313 A1
(43) Pub. Date: May 13, 2010

(54) A PHOTOVOLTAIC MODULE OR PANEL WITH A CERAMIC SUPPORT SLAB

(75) Inventor: Franco Stefani, Sassuolo (IT)

Correspondence Address: Pearne & Gordon LLP, 1801 East 9th Street, Suite 1200, Cleveland, OH, 44114-3108, US

(73) Assignee: SYSTEM S.P.A., 41042 Fiorano Modenese (Modena) (IT)

(21) Appl. No.: 12/594,924

(22) PCT Filed: Apr. 26, 2007
(86) PCT No.: PCT/IT07/00306

§ 371 Date: Oct. 6, 2009

(51) Int. Cl. H01L 31/042

(52) U.S. Cl. 136/244

(57) ABSTRACT

A photovoltaic module (1) comprises a plurality of photovoltaic cells (100), electrically interconnected to define a photo-active surface (2). The photovoltaic cells (100) being closed between a front covering layer (3a) and a back covering layer (3b) which are electrically insulating, the front covering layer (3a) being frontally covered by a frontal covering element (4) having a mechanical protection function for the photovoltaic cells (100). The back covering layer (3b) being posteriorly supported by a support element, the support element being a ceramic slab of a limited thickness.

### TECHNICAL FIELD

The invention relates to a photovoltaic module or panel.

In response to the need to diversify sources of energy production, dictated by concerns related to exhaustion of present sources as well as the proven climate-altering properties of fossil fuels, in recent decades there has been a progressive development of photovoltaic technology.

### BACKGROUND ART

Various technologies are known for photovoltaic modules: the most frequently present on the market, thanks to their cheapness and relative reliability, are modules constituted by cells made of mono- or poly-crystalline materials.

These cells are constituted by sheets made of a semiconductor material, almost always silicon, specially doped with atoms belonging to the III or the V group in the periodic table of elements, making a p-n junction. The sheets are treated with an anti-reflection coating on the surface exposed to the solar light (the n layer) in order to reduce loss of performance due to solar energy reflection on the part of the silicon.

The cells are generally used in combination; in these cases an electrically interconnected lattice of cells is realised, defining the photo-active surface of the module.

The module comprises various superposed layers, the cell lattice being only one of these.

Primarily the cells must be insulated between two layers of a dielectric material in order to ensure correct functioning. Generally sheets of sealing resin are used, in most cases EVA (ethyl-vinyl acetate).

In general there is a frontal glass protection for the sealed cell lattice. The front side of the module, here as in the rest of this document, is considered to be the side which is predisposed to be exposed to solar light. The front part of the module is consequently the side corresponding to the layer of n-type doped silicon, while the back part corresponds to the p-type layer of doped silicon. The protective glass guarantees a good transmission of the light, as well as ensuring mechanical protection of the device cells.

Finally, posteriorly with respect to the sealed lattice, there is a posterior closure having mainly device supporting functions. The material used in making the posterior closure must satisfy the obvious need for economy, mechanical resistance and low coefficient of thermal dilation, and possibly should also be an electrical insulator. Further, the material must be easily available in large-size slabs. Materials commonly used in the prior art for the production of the posterior closure are tempered glass, coloured or not, and polyvinylfluoride (PVF, commercially known as Tedlar®).

However, considering the transparency of EVA resins and the possible presence of non-covered spaces among the cells making up the lattice or beyond the perimeter thereof, the posterior closure can be seen in the mounted module.

In the case of glass or PVF panels, the mounted panel can be unattractive, especially given the lack of overall aesthetic uniformity with respect to the materials normally used for the construction of buildings.

### BRIEF SUMMARY OF THE INVENTION

The main aim of the present invention is to obviate the drawbacks in the prior art by providing a photovoltaic module which has a posterior closure that is homogeneous when placed in a context of other materials normally used in building design.

A further aim of the present invention is to give rise to a photovoltaic module which, by conformation and configuration, is particularly suitable for use as a structural and bearing module in cladding large surfaces.

An advantage of the present invention relates to the ease and cheapness of production of the photovoltaic modules of the invention, which exhibit large exposure surfaces.

A further advantage of the present invention concerns its cheapness, its mechanical and electrical resistance and the low coefficient of thermal dilation of the posterior closure of the photovoltaic panel of the invention.

### BRIEF DESCRIPTION OF THE DRAWINGS

Other characteristics and advantages of the invention will better emerge from the detailed description that follows of a preferred embodiment of the invention illustrated purely by way of non-limiting example in the accompanying figures of the drawings, in which:

FIG. 1 is a perspective exploded view of the photovoltaic module of the present invention;

FIG. 2 is a schematic view of a section of a photovoltaic module according to the present invention.

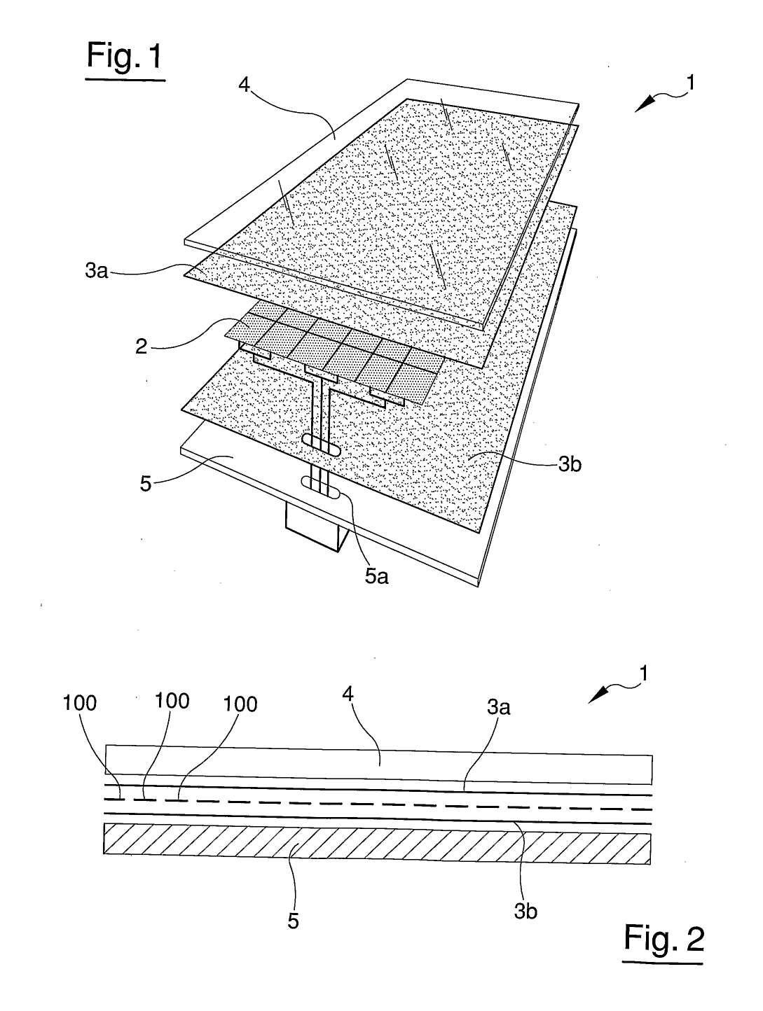

### DISCLOSURE OF INVENTION

With reference to the figures of the drawings, 1 denotes in its entirety a photovoltaic module according to the present invention.

The photovoltaic panel 1 comprises a plurality of photovoltaic cells 100 which are electrically interconnected to define a photo-active surface 2. The electrical interconnection of the photovoltaic cells 100, interconnected in a lattice, is preferably realised using a grid made of a conductor material, each cell being connected to the adjacent cells by metallic connectors commonly known as ribbons.

The totality of cells and ribbons is closed between a front covering layer 3a and a back covering layer 3b. Further, the front covering layer 3a is frontally covered by a frontal covering element 4, while the back covering layer 3b is supported posteriorly by a support element.

The covering layers 3a, 3b are made of an insulating material, as their main function is to electrically isolate the lattice of photovoltaic cells 100. It is, however, also important for the covering layers 3a, 3b to seal the photovoltaic cells in order to eliminate risks of corrosion. The layers 3a, 3b advantageously also function as bonds with respect to the frontal covering element 4 and the support element.

Finally, and importantly, at least the front covering layer 3a should be transparent in order to be permeable to the photons, which when frontally striking the device must encounter no obstacles to reaching the photoactive surface 2.

To satisfy the above requirements, covering layers 3a, 3b made of inert resin glue are advantageously used, preferably made of EVA (vinyl-ethyl acetate). EVA is a monomer which when brought to a temperature of 150/160° C. polymerises, sealing the cell lattice internally and performing the above-cited bonding action between the elements making up the module. EVA is transparent after polymerisation. Polymerisation is preferably done in a hermetic environment in order to prevent formation of air bubbles internally of the covering layers 3a, 3b. The thickness of the covering layers 3a, 3b is in the preferred embodiment of about half a millimetre.

The front covering layer 3a is frontally covered by the frontal covering element 4, which has the function of mechanically protecting the photovoltaic cells 100 behind it. Generally the frontal covering element 4 is made of tempered glass which must be able to ensure good mechanical resistance and excellent light transmission. The thickness of the frontal covering element 4 is preferably comprised between 3.2 and 8 millimetres.

The support element is advantageously constituted by a ceramic slab 5 of limited thickness. The fact that the slab is made of a ceramic material gives it an appearance which achieves a homogeneous effect when the slab is used in context with other commonly-used materials in the field of construction. Further, the limited thickness of the slab means that overall the device is not unwieldy and facilitates transport and installation. The ceramic slab 5 preferably has a thickness not greater than 3 millimetres and not less than a millimetre and a half. The ceramic slab 5 is preferably made of vitrified ceramic powders, realised by firing a slab-shaped body obtained by ceramic powder pressing. At least two holes 5a can be made in the ceramic slab 5 in order to pass the electrical connections for the panel through. Vitrified ceramic is an excellent material for the purpose, as it fully satisfies the requisites of cheapness, electrical resistance to environmental conditions, as well as having the required low coefficient of thermal dilation.

The main dimensions of the ceramic slab 5 and consequently those of the whole photovoltaic module 1 can be even very large, resulting in an extensive surface area of the slab. Preferably the main dimensions of the ceramic slab 5 are 3 metres in length by one metre in width.

The considerable surface obtained represents an advantage with respect to the prior art, according to which it is normally difficult to produce panels having large dimensions using Tedlar® glass having active elements made of silicon wafer.

1). A photovoltaic module (1) comprising a plurality of photovoltaic cells (100), electrically interconnected to define a photo-active surface (2), the photovoltaic cells (100) being closed between a front covering layer (3a) and a back covering layer (3b) which are electrically insulating, the front covering layer (3a) being frontally covered by a frontal covering element (4) having a mechanical protection function for the photovoltaic cells (100), the back covering layer (3b) being posteriorly supported by a support element, the support element being a ceramic slab (5) of a limited thickness.

2). The photovoltaic module (1) of claim 1, wherein the ceramic slab (5) has a thickness of 3 millimetres or less.

3). The photovoltaic module (1) of claim 2, wherein the ceramic slab (5) is of a thickness of 1.5 millimetres or more.

4). The photovoltaic module (1) of claim 1, wherein the ceramic slab (5) is made of vitrified ceramic material made by firing a slab-form product obtained by pressing ceramic powders.

5). The photovoltaic module of claim 4, wherein the ceramic slab (5) is obtained by pressing ceramic powders in a continuous production line.

6). The photovoltaic module (1) of claim 5, wherein the ceramic slab (5) has main dimensions which result in a large surface area thereof.

7). The photovoltaic module (1) of claim 6, wherein the main dimensions of the ceramic slab (5) are of one metre and three metres.

8). The photovoltaic module (1) of claim 1, wherein the front covering layer (3a) and the back covering layer (3b) comprise an inert resin glue.

9). The photovoltaic module (1) of claim 7, wherein the front covering layer (3a) and the back covering layer (3b) comprise vinyl-ethylic acetate.
